(19) United States
(12) Patent Application Publication
(10) Pub. No.: US 2006/0249732 A1
(43) Pub. Date: Nov. 9, 2006

(54) Manufacturing method of display apparatus

(75) Inventors: Tomoyuki Shirasaki, Higashiyamato-shi (JP); Minoru Kumagai, Tokyo (JP); Tadahisa Tohyama, Akishima-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 11/416,047

(22) Filed: May 2, 2006

(30) Foreign Application Priority Data
May 6, 2005 (JP) 2005-134787

(51) Int. Cl. H01L 29/04

(52) U.S. Cl. 257/59

(57) ABSTRACT

There is provided a manufacturing method of a display apparatus including a display panel in which a plurality of display pixels each having an organic electroluminescent element are arranged. A liquid-repellant coating is formed on a side of one surface of an insulating substrate constituting the display panel. A region alone in which each display pixel is formed is irradiated with a laser beam to modify a part of the liquid-repellant coating, in the pixel forming region, thereby providing lyophilicity thereto. A carrier transport layer is formed in the pixel forming region.

### CROSS-REFERENCE TO RELATED APPLICATIONS

This application is based upon and claims the benefit of priority from prior Japanese Patent Application No. 2005-134787, filed May 6, 2005, the entire contents of which are incorporated herein by reference.

### BACKGROUND OF THE INVENTION

1. Field of the Invention

The present invention relates to a manufacturing method of a display apparatus, and more particularly to a manufacturing method of a display apparatus including a display panel in which a plurality of display pixels each including of an organic electroluminescent element are arranged.

2. Description of the Related Art

In recent years, there have been actively carried out studies and development of a display (a display apparatus) including a light-emitting element type display panel in which self-luminous elements such as organic electroluminescent elements (which will be referred to as “organic EL elements” hereinafter) or light-emitting diodes (LEDs) are two-dimensionally arranged as a next-generation display device which follows a liquid crystal display apparatus (LCD) which is in heavy use as a monitor or a display of a personal computer, a video device, a portable information device or the like.

In particular, a light-emitting element type display for which an active matrix drive mode is adopted has very advantageous characteristics in that a reduction in thickness and weight is possible as compared with a liquid crystal display apparatus. That is because, in the light-emitting element type display, a display response speed is high, there is no viewing angle dependence, a high luminance/high contrast can be realized, high resolution of a display image quality can be achieved, power consumption or the like can be reduced, and a backlight is not required, while the liquid crystal display apparatus.

Here, a brief description will be given as to an organic EL element as an example of a self-luminous element applied to the light-emitting element type display.

FIG. 4 is a schematic cross-sectional view showing a schematic structure and an operation principle of the organic EL element.

As shown in FIG. 4, the organic EL element generally has a configuration in which an anode electrode 112 consisting of a transparent electrode material such as indium tin oxide (ITO), an organic EL layer 113 consisting of an organic compound (an organic material) or the like and a cathode electrode 114 consisting of a metal material and having reflection characteristics are sequentially superimposed on one surface side (an upper side in the drawing) of a transparent insulating substrate 111 such as a glass substrate.

Here, the organic EL layer 113 has a configuration in which, e.g., a hole transport layer (a hole injection layer) 113a made of an organic-polymer-based hole transport material and an electron transporting light-emitting layer (a light-emitting layer) 113b made of an organic-polymer based electron transporting light-emitting material are superimposed. Incidentally, although not shown, such an organic EL element is configured to be shut off from outside air by sealing and closing one surface side (the upper side in the drawing) of the insulating substrate 111 by using, e.g., a sealing layer made of, e.g., an epoxy-based resin or a sealing substrate (sealing glass or a sealing film).

In the organic EL element having such an element configuration, as shown in FIG. 4, when a positive voltage is applied to the anode electrode 112 and a negative voltage is applied to the cathode electrode 114 from a direct-current voltage source 115, light hν is emitted based on an energy generated due to recoupling of a hole injected in the hole transport layer 113a and an electron injected in the electron transporting light-emitting layer 113b in the organic EL layer 113.

This light hν is transmitted through the anode electrode 112 formed of a transparent electrode material or reflected by the cathode electrode 114 having reflection characteristics to be emitted toward the other surface side (a lower side in the drawing; a visual field side) of the insulating substrate 111 as indicated by arrows. At this time, a light emission intensity of the light hν is controlled in accordance with a quantity of current flowing between the anode electrode 112 and the cathode electrode 114.

In the above-described organic EL element, various methods have been invented as a manufacturing process of forming the hole transport layer 113a and the electron transporting light-emitting layer 113b constituting the organic EL layer 113. As an example of such a method, it is considered that a droplet discharge mode (a so-called an inkjet mode) is effective. In the droplet discharge mode, a liquid material in which the above-described organic-polymer-based hole transport material and/or electron transporting light-emitting material is dispersed or dissolved in a solvent is discharged in the form of droplets and applied to a light-emitting region of each display pixel (that is, an organic EL element forming region).

FIGS. 5A to 5I are process cross-sectional views showing a first example of a manufacturing process of an organic EL element in a prior art, and FIGS. 6A to 6F are process cross-sectional views showing a second example of the manufacturing process of the organic EL element in the prior art. Here, like reference numerals denote structures equivalent to those in an element structure of the above-described EL element.

According to the first example of the manufacturing process of the organic EL element, first, as shown in FIG. 5A, the anode electrode 112 made of a transparent electrode material such as at least ITO is formed in accordance with each region Ael where each organic EL element is formed (an organic EL element forming region) on one surface side (the upper side in the drawing) of the transparent insulating substrate 111. Then, as shown in FIG. 5B, a barrier (a bank) 121 made of an insulating resin material or the like is formed in a boundary region Abd between display pixels adjacent to each other. Here, an upper surface of the anode electrode 112 is exposed in the organic EL element forming region Ael surrounded by the barrier 121.

Subsequently, as shown in FIG. 5C, a surface of the insulating substrate 111 (which is precisely upper surfaces of each anode electrode 112 and each barrier 121) is irradiated with ultraviolet rays UV in an oxygen gas atmosphere. As a result, active oxygen radicals are generated in the anode electrodes 112 to decompose and remove organic matters on the ITO surface constituting the anode electrodes 112, thereby realizing hydrophilicity (or lyophilicity). Further, radicals are also generated on/in the surface of each barrier 121, thus achieving hydrophilicity.

Then, the upper surfaces of the anode electrodes 112 and the barriers 121 subjected to hydrophilic processing are irradiated with ultraviolet rays UV in a fluoride gas atmosphere. As a result, fluorine is coupled on the surface of each barrier 121 to provide hydrophobic properties and, on the other hand, the surface of each anode electrode (ITO) 112 maintains the hydrophilicity.

Subsequently, as shown in FIG. 5D, an inkjet device is used to discharge an organic-polymer-based hole injection material HMC in the form of droplets from each of ink heads IHH so that this material is applied to the upper side of each anode electrode 112 having the hydrophilicity. Thereafter, drying processing is carried out so that the hole injection material HMC is settled on each anode electrode 112 as shown in FIG. 5E, thereby forming the hole injection layer 113a.

Then, likewise, as shown in FIG. 5F, a polymer-based light-emitting material EMC is discharged in the form of droplets from each of ink heads IHE so that the material is applied to the upper side of the hole injection layer 113a. Then, drying processing is carried out so that the light-emitting material EMC is settled as shown in FIG. 5G, thereby forming the light-emitting layer 113b. In the application processing of the hole injection material HMC, since the surface of each barrier 121 has hydrophobic properties, even if droplets of the hole injection material HMC are landed onto each barrier 121, they are repelled and applied on the hydrophilic region alone on each anode electrode 112 in each organic EL element forming region Ael. Furthermore, even if the light-emitting material EMC is brought down onto each barrier 121, it is repelled and applied to the upper side of the hole injection layer 113a alone.

Subsequently, as shown in FIG. 5H, the cathode electrode 114 made of an electrode material which includes lithium, barium or the like and has reflection characteristics is formed to face the anode electrodes 112 through at least the organic EL layer 113 (the hole injection layer 113a and the light-emitting layer 113b). Then, as shown in FIG. 5I, a protection insulating film or a sealing resin layer 115 is formed on the insulating substrate 111 including each cathode electrode 114 in each organic EL element forming region Ael, and a sealing substrate 116 is bonded. As a result, the organic EL element (an organic EL display panel) is brought to completion.

A manufacturing method of such an organic EL element is described in, e.g., Jpn. Pat. Appln. KOKAI Publication No. 2003-257656 in detail.

Moreover, according to the second example of the manufacturing process of the organic EL element, first, as shown in FIG. 6A, at least a first electrode 112 is formed in each organic EL element forming region Ael on one surface side of a transparent insulating substrate 111. Then, as shown in FIG. 6B, a hydrophobicity photocatalyst containing layer 131 which contains a photocatalytic material such as titanium oxide (TiO₂) is formed on the insulating substrate 111 and the first electrodes 112.

Subsequently, as shown in FIG. 6C, the photocatalyst containing layer 131 on the first electrodes 112 is selectively exposed to ultraviolet rays UV or the like by using a pattern-formed photomask PMK. As a result, a property of a part of the photocatalyst containing layer 131 on each first electrode 112 is modified to change wettability (hydrophilicity or lyophilicity is achieved). Here, since a part of the photocatalyst containing layer 131 which has not been subjected to exposure processing maintains hydrophobic properties, the layer having patterns of different wettabilities is formed on the insulating substrate 111.

Then, like the first example mentioned above, as shown in FIG. 6D, an inkjet device is used to apply an electroconductive embrocation and a light-emitting layer embrocation onto the region of the photocatalyst containing layer 131 on each first electrode 112 having the hydrophilicity, thereby sequentially forming a hole injection layer 113a and a light-emitting layer 113b in each region Ael. In this case, likewise, since the part of the photocatalyst containing layer 131 excluding the region above each first electrode 112 has the hydrophobic properties, the electroconductive embrocation and the light-emitting layer embrocation are repelled from the part, and hence they are not applied on this part.

Subsequently, as shown in FIGS. 6E and 6F, a second electrode 114 is formed on the light-emitting layers 113b to face at least the electrodes 112, and then a protection insulating film or a sealing resin layer 115 is formed on the second electrode 114. Additionally, a sealing substrate 116 is bonded for sealing. As a result, the organic EL elements (an organic EL display panel) are brought completion.

A manufacturing method of such an organic EL display panel is described in, e.g., Jpn. Pat. Appln. KOKAI Publication No. 2001-237069 in detail.

The above-described manufacturing method of the organic EL elements (the organic EL display panel) have the following problems.

That is, in each of the first and second manufacturing processes, the upper side alone of the first electrode 112 of each display pixel (each organic EL element forming region Ael) is subjected to hydrophilic processing (or lyophilic processing) to apply a carrier transport material to the organic EL element forming region alone where the organic EL element is formed, thereby forming the organic EL element.

In this case, for example, when the number of display pixels arranged in the display panel is increased to miniaturize a size of each display pixel (each pixel forming region) in order to achieve high resolution for image display, there is a problem that the carrier transport material is hard to be thinly and uniformly applied to the organic EL element forming region to constitute the organic EL element having a uniform film thickness.

That is because hydrophobic processing performed with respect to each barrier 121 provided to protrude in the boundary region between the respective pixel forming regions is insufficient in the first manufacturing process. Further, a peripheral portion of a liquid level or liquid film of an embrocation LQD rises along a side surface of the barrier 121 as shown in FIG. 7A due to surface tension of the embrocation LQD of the carrier transport material. Therefore, there occurs unevenness in film thickness. That is, a film thickness of the embrocation LQD is increased in the vicinity of the peripheral portion of the liquid level, and the same is reduced in the vicinity of a central part of the liquid level.

Furthermore, in the second manufacturing process, since the above-described barriers are not provided, it is possible to avoid a phenomenon that the pheripheral portion of the liquid level of the embrocation for the carrier transport material rises along the side surface. However, the periphery of each pixel forming region is surrounded by the hydrophobic regions, and hence the peripheral portion of the liquid level of the embrocation LQD is lowered due to the surface tension as shown in FIG. 7B. Therefore, unevenness in film thickness occurs. That is, a film thickness of the embrocation LQD is reduced in the vicinity of the peripheral portion of the liquid level, and the same is increased in the vicinity of the central part of the liquid level. It is to be noted that FIGS. 7A and 7B are schematic views illustrating problems of the manufacturing processes of the organic EL element in the prior arts

As described above, since the film thickness of the organic EL layer formed in each pixel forming region does not become uniform, a light emission driving current which is supplied in the time of a light-emitting operation intensively flows through a region where the film thickness is increased, and thus excitation light is emitted (the light-emitting operation is performed) in this thick region alone. Therefore, there is a problem that the numerical aperture indicative of a ratio of a light-emitting area in each pixel forming region is lowered and a display image quality is deteriorated.

Moreover, although the second manufacturing process mentioned above has the exposure step at which ultraviolet rays UV or the like are selectively applied in order to provide hydrophilicity to the photocatalyst containing layer in each pixel forming region (the first electrode), a highly accurate photomask PMK corresponding to a position of each display pixel on the display panel (the insulating substrate 111) is required and an exposure device which generates short-wavelength light having a high energy is necessary for such exposure processing.

Additionally, there is a problem of an increase in the number of steps or in cost in order to accurately form the photomask corresponding to each display pixel (the pixel forming region) miniaturized for high resolution of image display.

### BRIEF SUMMARY OF THE INVENTION

It is an object of the present invention to provide a manufacturing method of a display apparatus which can form an organic EL layer having a relatively uniform film thickness in pixel forming region of each display pixel by using a simple technique.

According to one aspect of the present invention, there is provided a manufacturing method of a display apparatus including a display panel in which a plurality of display pixels each having an organic electroluminescent element are arranged, the method comprising:

forming a liquid-repellant coating on a side of one surface of an insulating substrate constituting the display panel;

irradiating a region alone in which each display pixel is formed with a laser beam to modify a part of the liquid-repellant coating, in the pixel forming region, thereby providing lyophilicity thereto; and

forming a carrier transport layer (a hole transport layer or an electron transport layer) in the pixel forming region.

The ward “liquid-repellant” used in this specification means the property imparted to an object such as a film, so that the object repels a specific kind of liquid which is applied to the object.

The provision of the lyophilicity is preferably performed by irradiating the part of the liquid-repellant coating in the region alone, where each display pixel is formed, with the laser beam through a photocatalytic film interposed in an irradiation path of the laser beam to modify the part of the liquid-repellant coating, in the pixel forming region.

The manufacturing method of a display apparatus may further comprises forming, into a predetermined pattern shape, at least one of a pair of electrodes constituting the organic electroluminescent element in the pixel forming region, before forming the liquid-repellant coating.

The manufacturing method of a display apparatus may further comprises forming a barrier around the pixel forming region of each display pixel, before forming the liquid-repellant coating,

wherein the provision of the lyophilicity is performed by irradiating a part of the pixel forming region alone surrounded by the barrier with the laser beam to modify the part of the liquid-repellant coating, in the pixel forming region.

The laser beam for the provision of the lyophilicity is preferably set to have a wavelength which is not greater than 380 nm.

An irradiation area of the laser beam for the provision of the lyophilicity is preferably set to be equivalent to an area of the pixel forming region.

An irradiation area of the laser beam for the provision of the lyophilicity is preferably set to be narrower than an area of the pixel forming region.

Preferably, the laser beam for the provision of the lyophilicity scans the pixel forming region.

The pixel forming region is preferably irradiated with the laser beam for the provision of the lyophilicity through a photocatalytic film on which a mask pattern corresponding to the pixel forming region is not formed.

According to the manufacturing method of a display apparatus of the present invention, a spot of a laser beam is directly applied to a part of a liquid-repellant coating alone in a pixel forming region (an organic EL element forming region) of a liquid-repellant coating formed on an insulating substrate. As a result, lyophilicity can be provided to this region alone, and lyophlic-liquid-repellant patterns (patterns having different wettabilities) can be formed on the insulating substrate, thereby forming an organic EL layer (a carrier transport layer) having a uniform film thickness.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIGS. 1A to 1F are process cross-sectional views showing a first embodiment of a manufacturing method of a display panel (an organic EL element) applied to a display apparatus according to the present invention;

FIGS. 2A to 2E are process cross-sectional views showing a second embodiment of the manufacturing method of the display panel (the organic EL element) applied to the display apparatus of the present invention;

FIG. 3 is a process cross-sectional view showing the second embodiment of the manufacturing method of the display panel (the organic EL element) applied to the display apparatus of the present invention;

FIG. 4 is a schematic cross-sectional view showing a schematic configuration and an operation principle of the organic EL element;

FIGS. 5A to 5I are process cross-sectional views showing a first example of a manufacturing process of an organic EL element according to a prior art;

FIGS. 6A to 6F are process cross-sectional views showing a second example of the manufacturing process of the organic EL element according to the prior art; and

FIGS. 7A and 7B are schematic views illustrating problems in the manufacturing processes of the organic EL element according to the prior art.

### DETAILED DESCRIPTION OF THE INVENTION

A manufacturing method of a display apparatus according to the present invention will now be described in detail based on embodiments.

### First Embodiment

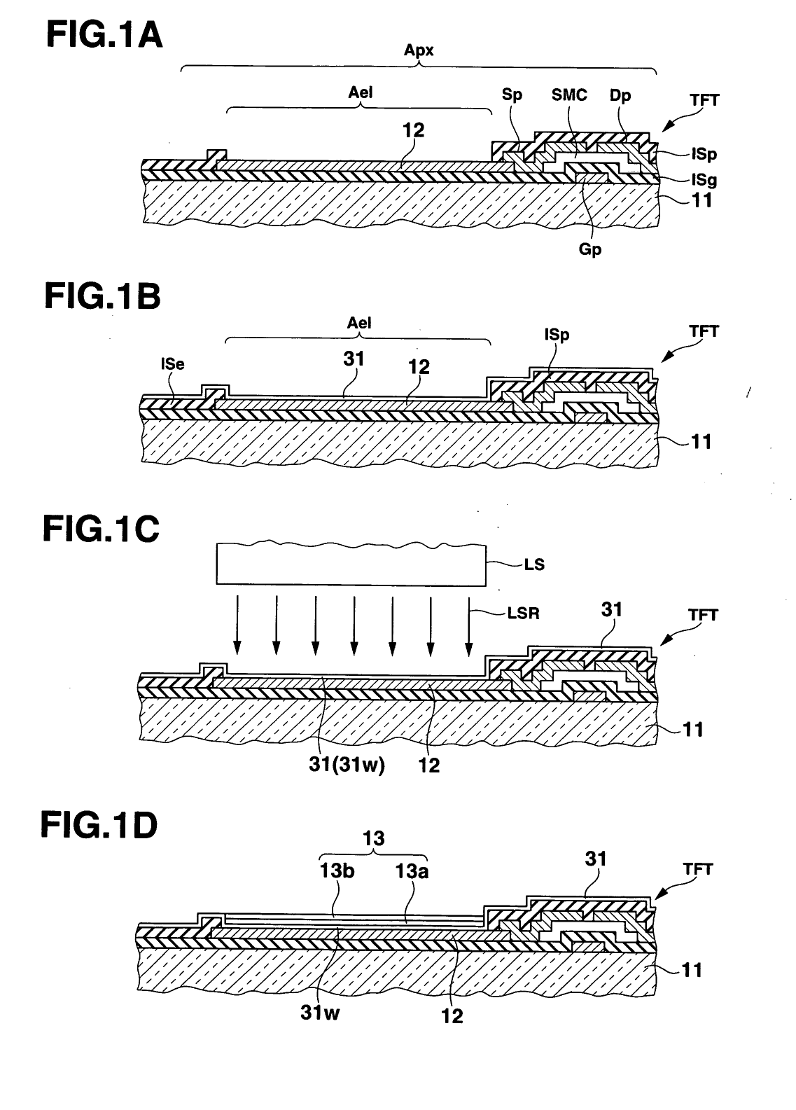

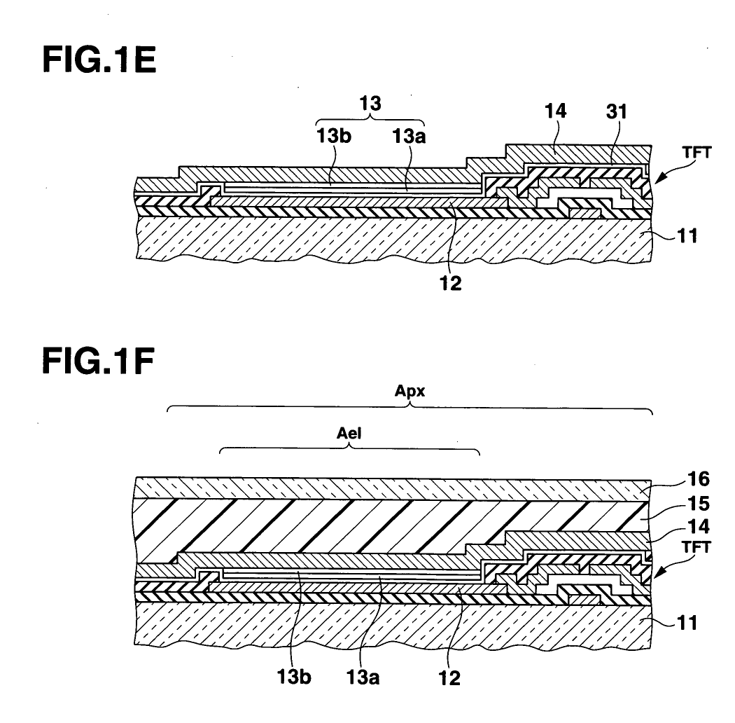

FIGS. 1A to 1F are process cross-sectional views showing a first embodiment of a manufacturing method of a display panel (an organic EL element) applied to a display apparatus according to the present invention. It is to be noted that like terms or like reference numerals denote the same structures as those in the prior art mentioned above.

According to a manufacturing method of a display panel (organic EL elements) applied to a display apparatus of the present invention, first, as shown in FIG. 1A, a plurality of pixel electrodes (electrode layers) 12 each of which is an anode electrode of the organic EL element and is made of a transparent electrode material are formed to be arranged in a matrix form in respective pixel forming regions Apx on one surface side of a transparent insulating substrate 11 formed of, e.g., glass, and a plurality of thin film transistors TFT each of which controls a supply state of a light emission driving current to each pixel electrode 12, an anode-side wiring line layer (not shown) and others are formed. Then, as shown in FIG. 1B, a liquid-repellant coating (a liquid-repellant membrane) 31 is thinly formed on an upper side of the insulating substrate 11 including an upper side of this pixel forming region Apx. Since the liquid-repellant coating 31 is very thin, it does not deteriorate all of carrier injection properties of each pixel electrode 12 with respect to a later-described organic EL layer 13 (e.g., a hole transport layer 13a).

Here, the pixel electrode 12 is obtained by, e.g., forming a film of a transparent electrode material such as a compound or a mixture containing at least one of indium oxide, zinc oxide and tin oxide (e.g., indium tin oxide (ITO), indium zinc oxide or the like) by an electron beam evaporation technique, a sputtering technique, an ion plating technique or the like and then patterning the obtained film in accordance with a planar shape of the organic EL element.

Further, the thin film transistor TFT is provided at a rim portion of an organic EL element forming region Ael in each pixel forming region Apx and preferably in the vicinity of a boundary region with respect to one of four display pixels adjacent to each other. In FIG. 1A, reference character Gp denotes a gate electrode of the thin film transistor TFT; Sp, a source electrode of the thin film transistor TFT formed to be electrically connected with each pixel electrode; Dp, a drain electrode of the tin film transistor TFT formed to be connected with a supply source of a light emission driving current fed to the organic EL element; ISg, an gate insulating film which is formed on a substantially entire upper surfaces of the gate electrode Gp and the substrate 11, and partially positioned between the gate electrode Gp, and the source and drain electrodes Sp and Dp to isolate these electrodes from each other; and SMC, a semiconductor (silicon) layer forming a channel region. It is to be noted that the gate insulating film ISg is provided to extend from a forming region of the thin film transistor TFT to a lower layer of each pixel electrode 12 in the organic EL element forming region Ael. Furthermore, ISp designates a protection insulating film provided to cover the thin film transistor TFT. This protection insulating film ISp is formed to be positioned at a part between the pixel electrodes where a transistor is not formed among parts between the pixel electrodes, and serves to insolate the pixel electrodes from each other.

Next, as shown FIG. 1A, a liquid-repellant coating 31 is formed on the pixel electrode 12 in the organic EL element forming region Ael, and on the protection insulating film ISp of the thin film transistor TFT (or this protection insulating film ISp and also an inter-element insulating film ISe of a frame-shape formed in a boundary region between the adjacent display pixels) in regions other than the organic EL element forming region Ael. The liquid-repellant coating 31 is obtained by, e.g., temporarily soaking the insulating substrate 11 provided with said members (assembly) in a liquid solution of a silane compound (especially a silazane compound) having a functional group containing fluorine or the like demonstrating liquid-repellant properties and then vaporizing a solvent in the liquid solution attached to the upper side of the assembly. The liquid-repellant coating 31 is formed in a state where a thin film consisting of the silazane compound having liquid-repellant properties is chemically absorbed or attached to the surfaces of the pixel electrode 12 and the insulating films ISp and ISe.

Then, as shown in FIG. 1C, a laser beam oscillation source LS is arranged above the organic EL element forming region Ael (i.e., a region above the pixel electrode 12), and it directly applies a laser beam LSR as indicated by arrows (without using a mask) to a part of the liquid-repellant coating 31 positioned in the organic EL element forming region Ael of the liquid-repellant coating 31. As a result, properties of this part of the liquid-repellant coating are modified, and lyophilicity is provided thereto. Here, the laser beam LSR is set to have a wavelength of, e.g., 380 nm or below and converged into a spot shape to have a predetermined irradiation area (or a beam diameter).

When such a laser beam LSR is applied, ozone is generated on the irradiated surface of the liquid-repellant coating 31 and substituted by functional group hydroxyl (—OH) demonstrating liquid-repellant properties, thereby providing lyophilicity. As a result, the organic EL element forming region Ael alone has lyophilic properties, and other regions surrounding the region Ael maintain liquid-repellant properties. Such lyophilic processing is individually executed in accordance with the organic EL element forming region Ael of each pixel forming region Apx on the upper side of the insulating substrate 11. Sequentially repeatedly executing such processing with respect to each pixel forming region Apx provides lyophilicity to the liquid-repellant coating part 31 in all the pixel forming regions Apx (forming a lyophilic layer 31w).

Here, as an irradiation method of the laser beam LSR with respect to the organic EL element forming region Ael, an irradiation area (a beam diameter) of the laser beam emitted from the laser beam oscillation source LS may be set to have an area and a shape substantially equivalent to that of the organic EL element forming region Ael as an irradiation target so that lyophilicity may be provided to the organic EL element forming region Ael of each pixel forming region Apx by applying the laser beam to this area for only one time. Alternatively, an irradiation area of the laser beam (a beam diameter) may be set to have an area and a shape smaller than that of the organic EL element forming region Ael so that the laser beam LSR is continuously applied like scanning to the organic EL element forming region Ael of each pixel forming region Apx, thereby providing lyophilicity to this area. Since lyophilicity can be provided to an arbitrary position or portion of the liquid-repellant coating 31 by the laser beam LSR in this manner, lyophilic/liquid-repellant patterning can be accurately performed without using a photomask which causes the laser beam LSR selectively expose the film.

Then, as shown in FIG. 1D, like the example of the prior art, an inkjet device is used to discharge, e.g., polyethylene dioxythiophene/polystyrene sulfonic acid aqueous solution (PEDOT/PSS: a dispersion liquid in which polyethylene dioxythiophene PEDOT as an electrocondutive polymer and polystyrene sulfonic acid PSS as a dopant are dispersed in a water-based solvent) as an organic compound containing liquid including an organic-polymer-based hole transport material in the form of droplets to be applied to the lyophilic liquid-repellant coating 31 (the lyophilic layer 31w) having the lyophilic properties on the pixel electrode 12. Then, a drying treatment is performed in a nitrogen atmosphere to remove the solvent. As a result, the organic-polymer-based hole transport material is settled on the pixel electrode 12, thereby forming the hole transport layer 13a as a carrier transport layer.

Here, since the droplet or droplets of the organic compound containing liquid (the hole transport material) applied to the upper side of the lyophilic layer 31w on the pixel electrode 12 have a higher wettability against the lyophilic layer 31w, the hole transport layer 13a having a uniform film thickness can be formed in the entire organic EL element forming region Ael. On the other hand, the organic compound containing liquid applied to the upper side of the liquid-repellant coating 31 which has not been sufficiently subjected to lyophilic processing is repelled, and hence it is not settled on this film.

Subsequently, likewise, the inkjet device is used to discharge, e.g., a liquid solution in which a polyfluorene-based or polyparaphenylenevinylene-based light-emitting material is dissolved in an organic solvent such as tetralin, tetramethylbenzene, mesitylene or xylene as an organic compound containing liquid including an organic-polymer-based electron transporting light-emitting material in the form of droplets to be applied to the upper side of the hole transport layer 13a. Then, a drying treatment is carried out in a nitrogen atmosphere to remove the solvent. As a result, the organic-polymer-based electron transporting light-emitting material is settled on the hole transport layer 13a, thereby forming the electron transporting light-emitting layer (a light-emitting layer) 13b as a carrier transport layer.

Here, since a liquid-repellant part of the liquid-repellant coating 31 has stronger liquid-repellant properties than the hole transport layer 13a, against the organic compound containing liquid (the electron transporting light-emitting material) applied to the upper side of the dried hole transport layer 13a tends, the hole transport layer 13a has a higher wettability than the liquid-repellant part of the liquid-repellant coating 31. Therefore, the electron transporting light-emitting layer 13b having a uniform film thickness can be formed in the entire organic EL element forming region Ael. On the other hand, the organic compound containing liquid applied to the exposed upper surface of the part of the liquid-repellant coating 31 is repelled, and hence it is not settled on this upper surface. Moreover, since the solvent in the organic compound containing liquid has lipophilic properties (hydrophobic properties), the material of the hole transport layer 13a is rarely dissolved by this solvent.

Next, as shown in FIG. 1E, an electrode layer made of an electroconductive material having reflection characteristics which includes a material superior in electron injection properties such as lithium or barium is formed on the insulating substrate 11 including the pixel forming region Apx by an evaporation technique or a sputtering technique. Then an opposed electrode (the other electrode layer) 14 as a cathode electrode of the organic EL element to face the pixel electrodes 12 through at least the hole transport layers 13a and the electron transporting light-emitting layers 13b, an opposed electrode wiring line layer (not shown) which is to be connected with a predetermined power supply voltage such as a ground potential and others are formed.

Subsequently, as shown in FIG. 1F, a protection insulating film or a sealing resin layer 15 is formed on the upper surface of the resultant assembly containing the opposed electrode 14 in each pixel forming region Apx and the opposed electrode wiring line layer, and then a sealing substrate 16 is bonded. As a result, the organic EL elements (the organic EL display panel) are brought to completion.

As described above, the manufacturing method of the organic EL element (the organic EL display panel) according to this embodiment is characterized in that a spot of the laser beam having a short wavelength (which is not greater than 380 nm) is directly applied to the part of the liquid-repellant coating 31 alone formed in the organic EL element forming region Ael (on the pixel electrode 12) on the insulating substrate 11 to provide lyophilicity to this area alone, whereby the lyophilic-hydrophobic patters (patterns having different wettabilities) are formed on the insulating substrate 11. As a result, the organic EL layer 13 (the hole transport layer 13a and the electron transporting light-emitting layer 13b) having a uniform film thickness on which the embrocation (the organic compound containing liquid) of the organic material (the hole transport material and the electron transporting light-emitting material) can be uniformly spread is formed in the entire organic EL element forming region Ael only.

According to such a manufacturing method of the organic EL element (the organic EL display panel), it is possible to form on the pixel electrode the lyophilic layer having excellent lyophilicity (wettability) with respect to the hole transport material or the electron transporting light-emitting material which is used to form the hole transport layer or the electron transporting light-emitting layer, and sufficient liquid-repellant properties can be maintained in the other regions (excluding the organic EL element forming region). Therefore, lowering of the end portion of the liquid level due to a surface tension of the embrocation of the organic material can be alleviated, thereby forming the organic EL layer having a relatively uniform film thickness.

Therefore, since a light emission driving current which is supplied at the time of a light-emitting operation of the organic EL element relatively uniformly flows through a substantially entire region of the organic EL layer, excitation light is emitted in a substantially entire region of the pixel forming region (the organic EL element forming region) (the light-emitting operation is carried out). Thus, an aperture ratio of the display panel can be improved to realize the display apparatus having an excellent display image quality.

Further, in the manufacturing method according to this embodiment, the part of the liquid-repellant coating in the organic EL element forming region (on the pixel electrode) is directly irradiated with the laser beam to provide lyophilicity to this part of the liquid-repellant coating. Therefore, a highly accurate photomask does not have to be used in order to selectively apply the laser beam. Further, the laser beam as short-wavelength light used for the lyophilic processing can be readily generated by using a general laser beam oscillation source. Therefore, a general-purpose or existing equipment can be used to form the organic EL layer (the organic EL element) having an excellent film quality in a simple and inexpensive manufacturing process.

In this embodiment, the description has been given as to the configuration in which the part of the protection insulating film ISp positioned between the display pixels adjacent to each other (the pixel boundary region) and the transistor are provided with a function of a barrier, and hence a special barrier is not formed. However, the present invention is not restricted thereto, and it may have a configuration in which a barrier is provided between the display pixels adjacent to each other like the configuration explained in conjunction with the prior art.

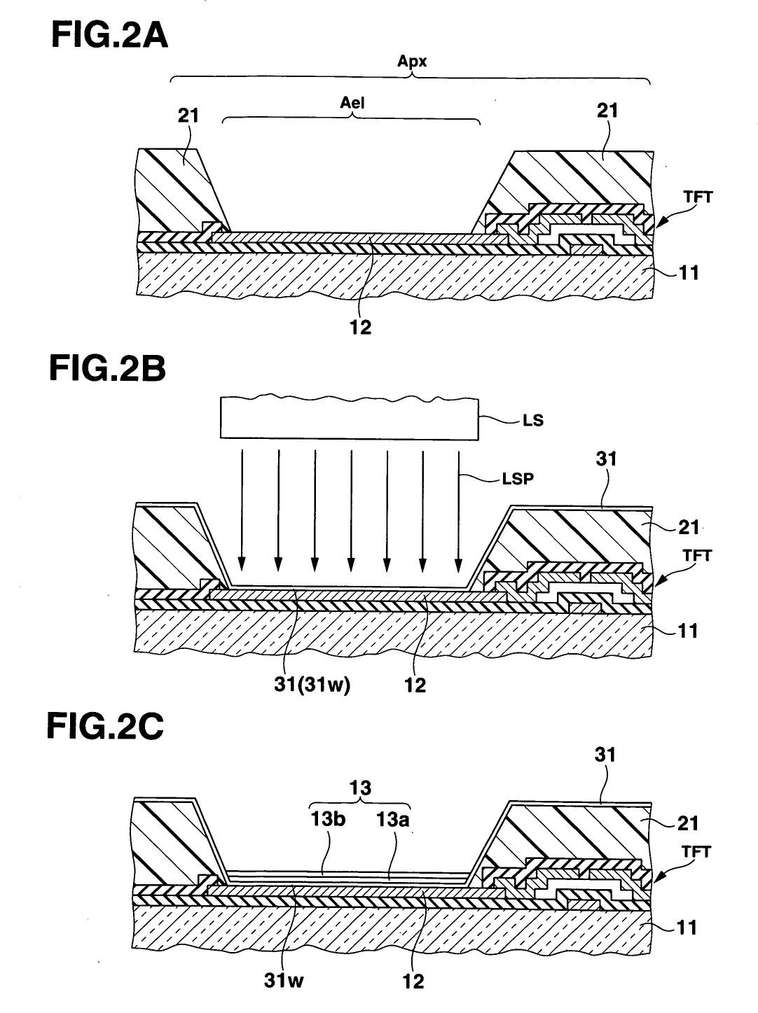

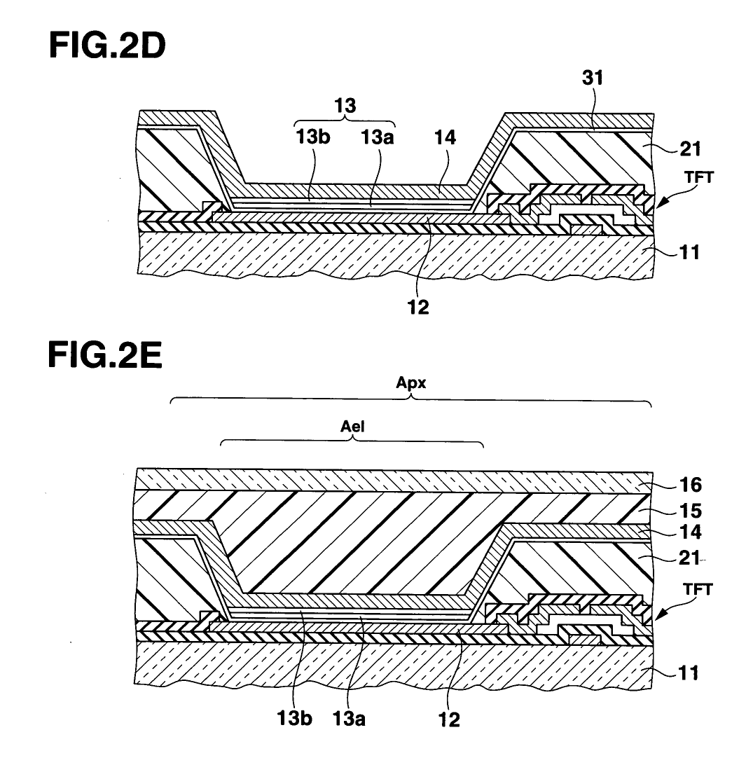

FIGS. 2A to 2E are process cross-sectional views showing another example of the manufacturing method of a display panel (an organic EL element) according to this embodiment.

That is, an insulating resin material with a predetermined film thickness (e.g., several μm) is formed on an entire region on one surface side of an insulating substrate 11 having each pixel electrode 12 and each thin film transistor TFT formed thereon as shown in FIG. 1A. Then, as shown in FIG. 2A, patterning is performed by a photolithography technique so that the resin material remains at least between display pixels adjacent to each other (a pixel boundary region), thereby forming each frame-like barrier (a bank) 21 having an inner side surface inclined at an angle which is less than 90 degrees (which is preferably 60 degrees to 80 degrees). As a result, the pixel electrode 12 is exposed in a pixel forming region Apx (that is, an organic EL element forming region Ael) surrounded by the barriers 21.

Subsequently, like the foregoing embodiment, as shown in FIG. 2B, a liquid-repellant coating 31 is formed on the insulating substrate 11, the pixel electrodes 12 and the barriers 21, and then the organic EL element forming region Ael surrounded by the barriers 21 alone is selectively irradiated with a laser beam LSR from a laser source LS, thereby providing lyophilicity to the part of the liquid-repellant coating 31 in this region (forming a lyophilic layer 31w).

Thereafter, as shown in FIG. 2C, an inkjet method is used to sequentially superimpose an organic EL layer 13 (a hole transport layer 13a and an electron transporting light-emitting layer 13b) on the lyophilic layer 31w in the organic EL element forming region Ael. Further, as shown in FIG. 2D, an opposed electrode 14 is formed to face the pixel electrodes 12 with the organic EL layers 13 disposed therebetween. Then, as shown in FIG. 2E, a sealing substrate 16 is bonded through a sealing resin layer 15 or the like, thereby bringing the organic EL elements (the organic EL display panel) to completion.

In such a manufacturing method of the organic EL element (the organic EL display panel), the lyophilic layer having excellent lyophilicity (wettability) with respect to an organic material (a hole transport material or an electron transporting light-emitting material) can be formed on the pixel electrode, and sufficient liquid-repellant properties can be maintained on the barrier surface. Therefore, unevenness in height of a liquid level due to a surface tension of an embrocation of the organic material can be alleviated, thus forming the organic EL layer (the hole transport layer and/or the electron transporting light-emitting layer) having a relatively uniform film thickness. Moreover, setting an inclination angle of each barrier 21 to be less than 90 degrees can further ease rising of a rim of the organic EL element forming region Ael.

### Second Embodiment

A second embodiment of the manufacturing method of the display apparatus according to the present invention will now be described.

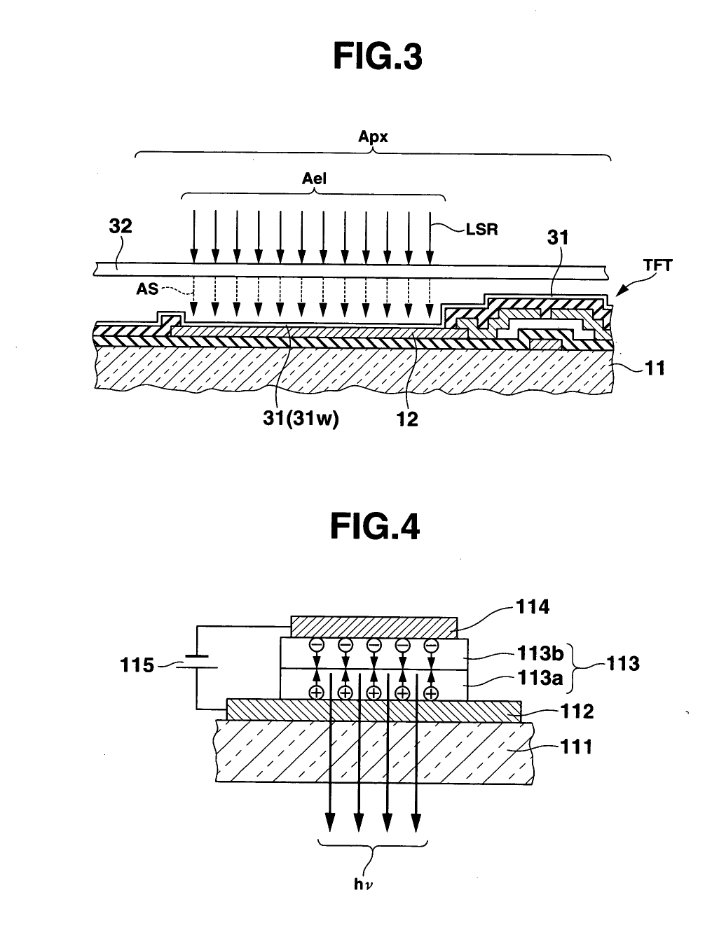

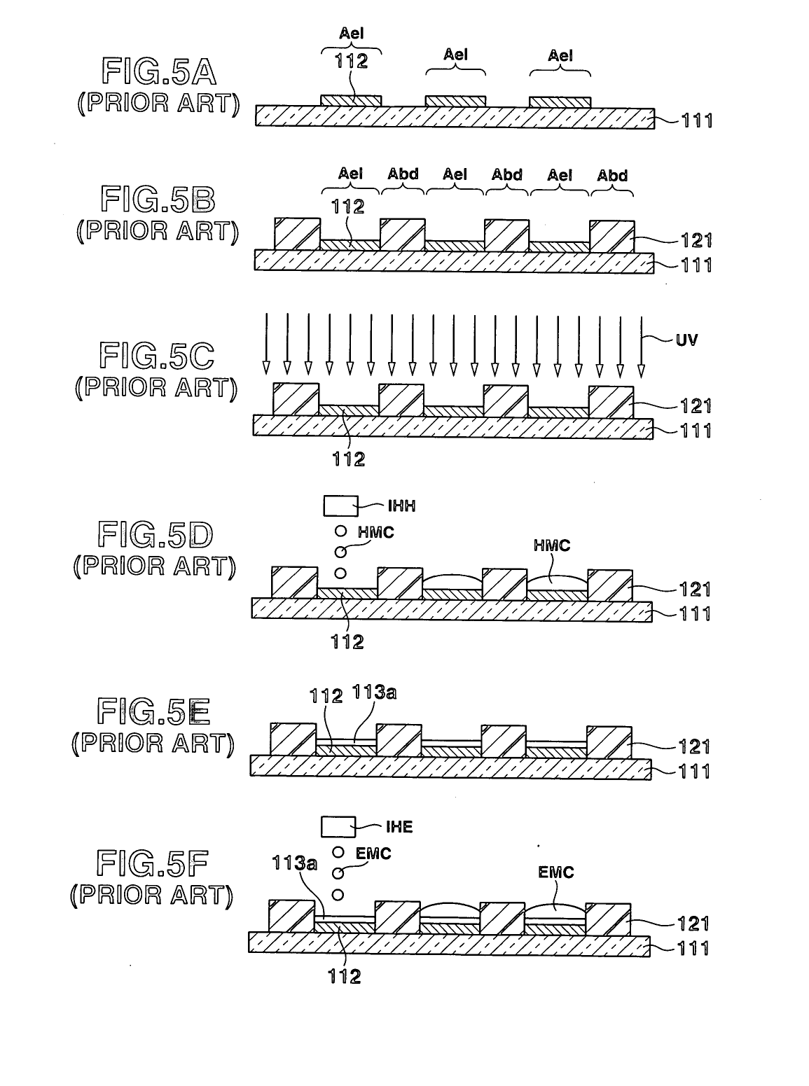

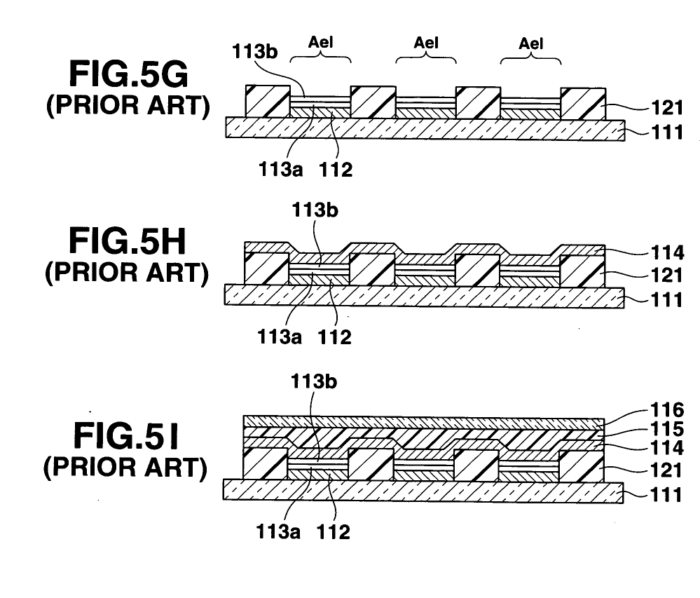

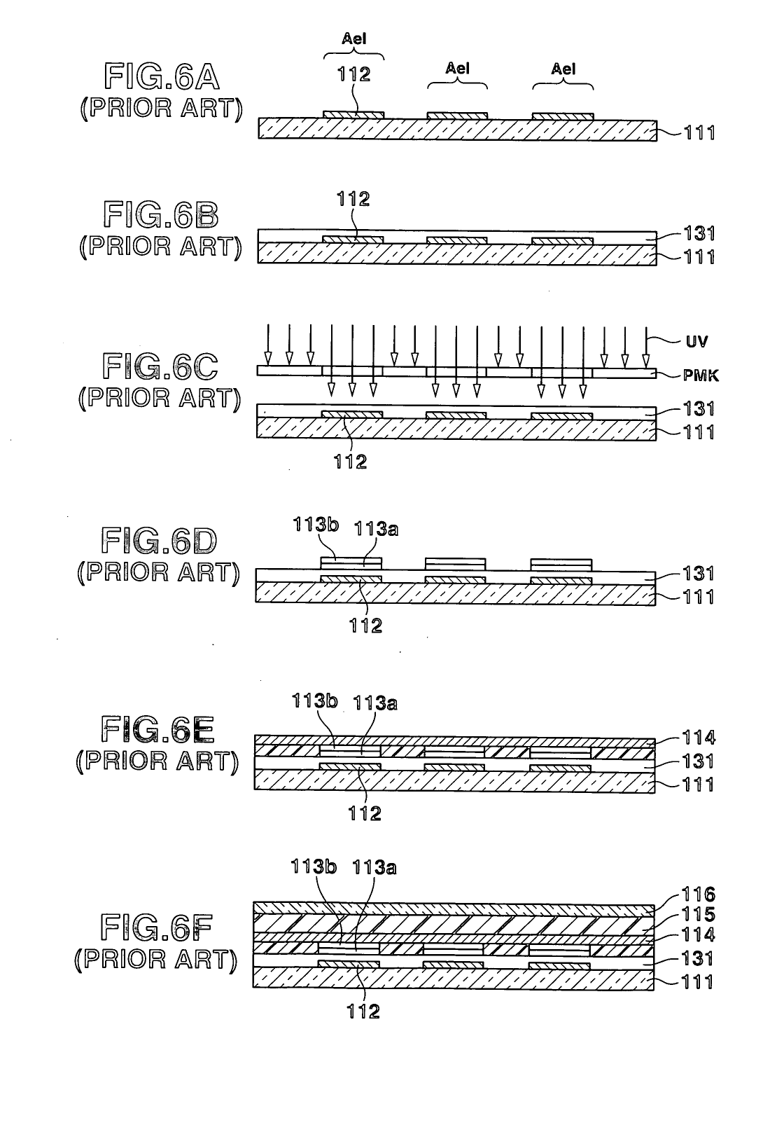

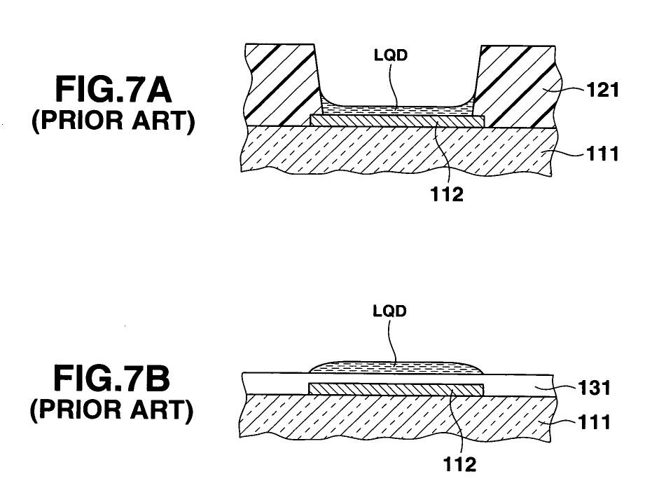

FIG. 3 is a process cross-sectional view showing the second embodiment of the manufacturing method of a display panel (an organic EL element) applied to the display apparatus according to the present invention. It is to be noted that the description on the same manufacturing steps as those in the foregoing embodiment will be simplified.

In the first embodiment mentioned above, the description has been given as to the manufacturing process in which the liquid-repellant coating 31 is formed on the upper side of the insulating substrate 11 on which the pixel electrode 12 and the thin film transistor TFT are formed in each pixel forming region Apx, and then the part of the liquid-repellant coating 31 in the organic EL element forming region Ael (on the pixel electrode 12) in each pixel forming region Apx alone is selectively irradiated with the laser beam LSR so that properties of the liquid-repellant coating part in this region are modified, thereby providing lyophilicity (forming the lyophilic layer 31w). However, the second embodiment has a manufacturing process in which a liquid-repellant coating 31 is formed on an upper side of an insulating substrate 11 having both pixel electrodes 12 and thin film transistors TFT formed thereon, and then a laser beam LSR is selectively applied through a photomask formed of a photocatalytic film, thus forming a lyophilic layer 31w.

According to the manufacturing method of the display panel (the organic EL element) applied to the display apparatus according to this embodiment, specifically, first, as shown in FIGS. 1A and 1B, the liquid-repellant coating 31 is formed in an entire region on one surface side of the insulating substrate 11 having the pixel electrodes 12 and the thin film transistors TFT formed thereon. Thereafter, as shown in FIG. 3, a photocatalytic film 32 (i.e., a photomask formed of a simple thin plate having no mask pattern formed thereon) formed of a photocatalytic material such as titanium oxide (TiO₂) is arranged on one surface side of the insulating substrate 11 having the liquid-repellant coating 31 formed thereover to be apart from a substrate surface, and the organic EL element forming region Ael (i.e., a region on the pixel electrode 12) in each pixel forming region Apx is selectively irradiated with a laser beam LSR having a wavelength of, e.g., 380 nm or below like the first embodiment.

When the photocatalytic film 32 in the region corresponding to the organic EL element forming region Ael is irradiated with the laser beam LSR as active light rays in this manner, active oxygen species (including free radicals) AS are generated in the photocatalytic film 32, and the active oxygen species AS downwardly move from the photocatalytic film 32 to provoke a chemical reaction (a catalytic reaction) with the liquid-repellant coating 31 in the region positioned directly below. A functional group including fluorine which demonstrates liquid-repellant properties in the liquid-repellant coating 31 is separated/left and substituted by a hydroxyl group (—OH) demonstrating lyophilicity. As a result, lyophilicity is provided to the part of the liquid-repellant coating 31, in this region, thereby forming the lyophilic layer 31w. As a result, the organic EL element forming region Ael alone demonstrates the lyophilic properties, and other regions maintain liquid-repellant properties.

The photocatalytic material applicable to the photocatalytic film 32 is not restricted to titanium oxide (TiO₂) mentioned above, and it is possible to apply one or more types of materials selected from zinc oxide (ZnO), tin oxide (SnO₂), strontium titanate (SrTiO₃), tungsten oxide (WO₃), ferric oxide (Fe₂O₃) and others. In particular, when a wavelength of the laser beam is set to 380 nm or below, it is desirable to apply titanium oxide (TiO₂) having an excitation wavelength of 380 nm or below to the photocatalytic film.

Then, like the first embodiment, the inkjet method is used to sequentially superimpose an organic EL layer 13 (a hole transport layer 13a and an electron transporting light-emitting layer 13b) on the lyophilic layer 31w in the organic EL element forming region Ael, and an opposed electrode 14 is formed to face the pixel electrodes 12 through the organic EL layers 13. Subsequently, a sealing substrate 16 is bonded through a sealing resin layer 15 or the like, thereby bringing the organic EL elements (the organic EL display panel) to completion.

As described above, according to the manufacturing method of the organic EL element (the organic EL display panel) of this embodiment, a spot of the laser beam LSR having a short wavelength (of 380 mm or below) is selectively applied to the liquid-repellant coating 31 formed in the pixel forming region Apx (the organic EL element forming region Ael) alone on the insulating substrate 11 through the photomask formed of the photocatalytic film 32 to provide lyophilicity to this region, thereby forming lyophilic-hydrophobic patterns (patterns having different wettabilities) on the insulating substrate 11.

According to such a manufacturing method of the organic EL element (the organic EL display panel), realization of lyophilicity of the liquid-repellant coating can be facilitated by the active oxygen species AS generated by application of the laser beam LSR to the photocatalytic film. Therefore, lyophilic processing can be efficiently performed by using a simple technique, and the lyophilic layer having very excellent lyophilicity (wettability) with respect to the organic material (the hole transport material or the electron transporting light-emitting material) can be formed on the pixel electrode. Therefore, the organic EL element having the organic EL layer with a uniform film thickness can be formed. The manufacturing method of the display apparatus according to the second embodiment can be likewise applied in the method described in conjunction with FIGS. 2A to 2E.

Additionally, in the foregoing embodiment, since an irradiation direction of the laser beam LSR is controlled, masking which generates the active oxygen species AS in the organic EL element forming region Ael alone does not have to be carried but with respect to the photocatalytic film 32 even if a catalytically active light rays are applied to the entire pixel forming region Apx. Therefore, a resolution is not restricted by a mask of the photocatalytic film 32, thereby forming the high-resolution organic EL element forming region Ael.

In each of the foregoing embodiments, a step exists between the protection insulating film ISp and the rim of the organic EL element forming region Ael. Further, there is also a step between the barrier 21 and the rim of the organic EL element forming region Ael. A liquid relatively tends to be collected at the rim of the organic EL element forming region Ael because of such steps. As a result, the carrier transport layer material which turns to the organic EL layer 13 is apt to be condensed. Therefore, in order to further uniform a film thickness of the organic EL layer 13 in the entire organic EL element forming region Ael, an irradiation time of the laser beam LSR at the rim of the organic EL element forming region Ael may be set shorter than an irradiation time at the center of the organic EL element forming region Ael or an irradiation intensity of the laser beam LSR at the rim of the organic EL element forming region Ael may be set weaker than an irradiation intensity at the center of the organic EL element forming region Ael so that the lyophilicity at the center of the organic EL element forming region Ael can be higher than that at the rim of the organic EL element forming region Ael.

Although the pixel electrode 12 is the transparent electrode in each of the foregoing embodiments, the present invention is not restricted thereto, and the pixel electrode 12 may be a reflection electrode formed of an electroconductive layer having light reflectivity or a laminated structure including a reflection electroconductive layer and a transparent electroconductive layer. When the pixel electrode 12 has the light reflectivity in this manner, light emitted from the organic EL layer 13 may be transmitted from the opposed electrode 14 side as light permeability of the opposed electrode 14.

Additionally, although the pixel electrode 12 and the opposed electrode 14 are respectively the anode electrode and the cathode electrode in each of the foregoing embodiments, the pixel electrode 12 and the opposed electrode 14 may be respectively a cathode electrode and an anode electrode.

Although the pixel electrode 12 is formed on the gate insulating film ISg in the foregoing embodiments, the present invention is not restricted thereto. The protection insulating film ISp may be formed to extend to the organic EL element forming region Ael, and then a contact hole from which the source electrode Sp is exposed may be formed in the protection insulating film ISp. Thereafter, the pixel electrode 12 may be formed to be electrically connected with the source electrode Sp. At this time, the protection insulating film ISp may have a laminated structure of a flattened film made of a photosensitive resin or the like in addition to a protection film formed of silicon nitride or the like.

In case of scanning the laser beam LSR in each of the foregoing embodiments, light irradiation direction controlling means such as a lens or a mirror may be arranged between the laser beam oscillation source LS and the liquid-repellant coating 31 to perform scanning. Further, at least one of the laser beam oscillation source LS and the insulating substrate 11 may be relatively two-dimensionally horizontally moved to effect scanning. Furthermore, the laser beam LSR may be repeatedly scanned at the same position in the organic EL element forming region Ael as required.

Moreover, the hole transport layer 13a and the electron transporting light-emitting layer 13b are sequentially formed in each of the foregoing embodiments, but the present invention is not restricted thereto, and the electron transporting light-emitting layer 13b and the hole transport layer 13a may be formed in the mentioned order.

Although the organic EL layer 13 is constituted of the hole transport layer 13a and the electron transporting light-emitting layer 13b in each of the foregoing embodiments, the organic EL layer 13 may be constituted of a single light-emitting layer, of a hole transport layer, a light-emitting layer and an electron transport layer, or of a hole transporting light-emitting layer and an electron transport layer. Moreover, other carrier transport layers may be appropriately added.

Additionally, although the barrier 21 is formed of an insulating resin material in the foregoing embodiments, a surface of the electroconductive barrier may be coated with an insulating film.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

What is claimed is:

1. A manufacturing method of a display apparatus including a display panel in which a plurality of display pixels each having an organic electroluminescent element are arranged, the method comprising:
forming a liquid-repellant coating on a side of one surface of an insulating substrate constituting the display panel;
irradiating a region alone in which each display pixel is formed with a laser beam to modify a part of the liquid-repellant coating, in the pixel forming region, thereby providing lyophilicity thereto; and
forming a carrier transport layer in the pixel forming region.

2. The manufacturing method of a display apparatus according to claim 1, wherein the provision of the lyophilicity is performed by irradiating the part of the liquid-repellant coating in the region alone, where each display pixel is formed, with the laser beam through a photocatalytic film interposed in an irradiation path of the laser beam to modify the part of the liquid-repellant coating, in the pixel forming region.

3. The manufacturing method of a display apparatus according to claim 1, further comprising forming, into a predetermined pattern shape, at least one of a pair of electrodes constituting the organic electroluminescent element in the pixel forming region, before forming the liquid-repellant coating.

4. The manufacturing method of a display apparatus according to claim 1, further comprising forming a barrier around the pixel forming region of each display pixel, before forming the liquid-repellant coating,
wherein the provision of the lyophilicity is performed by irradiating a part of the pixel forming region alone surrounded by the barrier with the laser beam to modify the part of the liquid-repellant coating, in the pixel forming region.

5. The manufacturing method of a display apparatus according to claim 1, wherein the laser beam for the provision of the lyophilicity is set to have a wavelength which is not greater than 380 nm.

6. The manufacturing method of a display apparatus according to claim 1, wherein an irradiation area of the laser beam for the provision of the lyophilicity is set to be equivalent to an area of the pixel forming region.

7. The manufacturing method of a display apparatus according to claim 1, wherein an irradiation area of the laser beam for the provision of the lyophilicity is set to be narrower than an area of the pixel forming region.

8. The manufacturing method of a display apparatus according to claim 1, wherein the laser beam for the provision of the lyophilicity scans the pixel forming region.

9. The manufacturing method of a display apparatus according to claim 1, wherein the pixel forming region is irradiated with the laser beam for the provision of the lyophilicity through a photocatalytic film on which a mask pattern corresponding to the pixel forming region is not formed.
